(19) United States
(12) Patent Application Publication
(10) Pub. No.: US 2025/0349554 A1
(43) Pub. Date: Nov. 13, 2025

(54) ANNEALING SYSTEM AND METHOD FOR USING THE SAME

(71) Applicant: Taiwan Semiconductor Manufacturing Co., Ltd., Hsinchu (TW)

(72) Inventors: Yi-Fan Chen, New Taipei (TW); Sen-Hong Syue, Zhubei (TW); Huicheng Chang, Tainan (TW); Yee-Chia Yeo, Hsinchu (TW)

(21) Appl. No.: 19/274,594

(22) Filed: Jul. 20, 2025

Related U.S. Application Data
(62) Division of application No. 17/648,577, filed on Jan. 21, 2022.
(60) Provisional application No. 63/214,499, filed on Jun. 24, 2021.

(51) Int. Cl. H01L 21/324; H01L 21/67; H01L 21/687

(52) U.S. Cl. CPC H01L 21/324; H01L 21/67115; H01L 21/67248; H01L 21/6875; H01L 21/68757

(57) ABSTRACT

A method includes placing a wafer on a susceptor, wherein the wafer has a first radius, wherein a top surface of the susceptor has a second radius that is greater than the first radius; using microwave radiation to heat the wafer and the susceptor; and removing the wafer from the susceptor.

### PRIORITY CLAIM AND CROSS-REFERENCE

This application is a divisional of U.S. patent application Ser. No. 17/648,577, filed on Jan. 21, 2022, which claims the benefit of U.S. Provisional Application No. 63/214,499, filed on Jun. 24, 2021, each application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography and etching processes in combination with dopant implantation and thermal annealing techniques to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise within each of the processes and techniques that are used, and these additional problems should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a plan view of a microwave annealing system, in accordance with some embodiments.

FIG. 2 illustrates a cross-sectional view of a microwave annealing system, in accordance with some embodiments.

FIG. 3 illustrates a perspective view of a microwave annealing system, in accordance with some embodiments.

FIGS. 4A, 4B, and 4C show distributions of electric field intensity during a microwave annealing process, in accordance with some embodiments.

FIGS. 5A, 5B, and 5C show data of electric field intensities during a microwave annealing process, in accordance with some embodiments.

FIGS. 6A, 6B, and 6C show data of electric field intensities during a microwave annealing process, in accordance with some embodiments.

FIG. 7 illustrates a flow chart of a microwave annealing process, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A wafer annealing system is provided in accordance with various exemplary embodiments. The wafer annealing system may be used to heat a wafer as part of a thermal treatment. The wafer may be heated to desired temperatures by performing a microwave anneal (MWA) process using the wafer annealing system. For example, a wafer may be placed on a susceptor, and microwave radiation used to heat the wafer and the susceptor. For some thermal treatments, it may be useful to achieve a relatively uniform temperature across the wafer. Embodiments described herein include an MWA system with a susceptor that has a width (e.g. a diameter) that is at least as large as the width of the wafer being heated. The use of a susceptor that has a width the same as or larger than the wafer can improve heating uniformity across the wafer and can reduce abrupt changes in electric fields near the edges of the wafer. The MWA system described herein may allow for improved heating of wafers and reduced chance of wafer damage due to thermal shock.

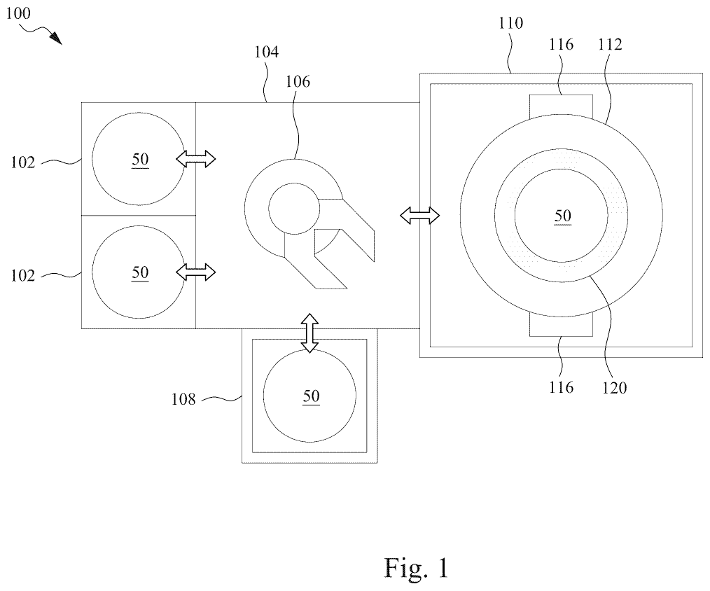

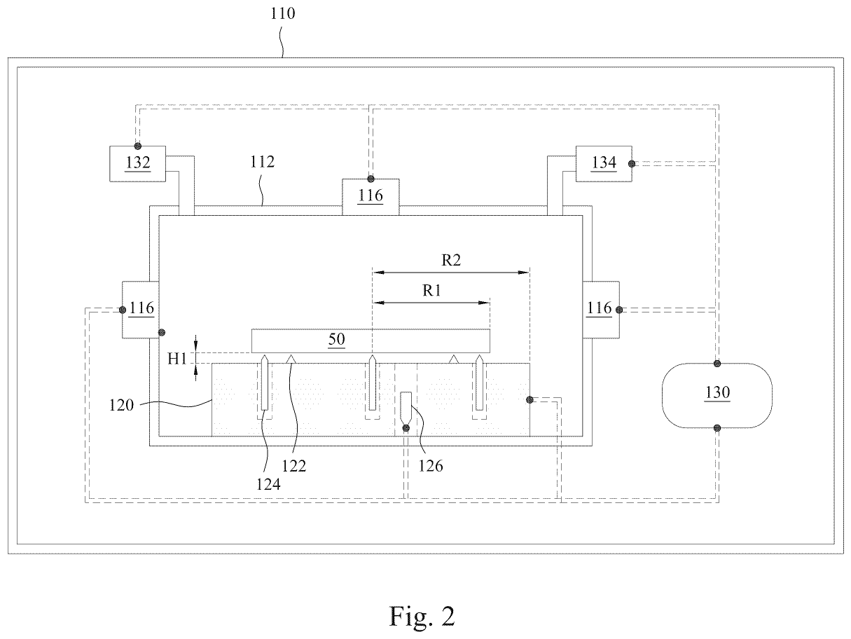

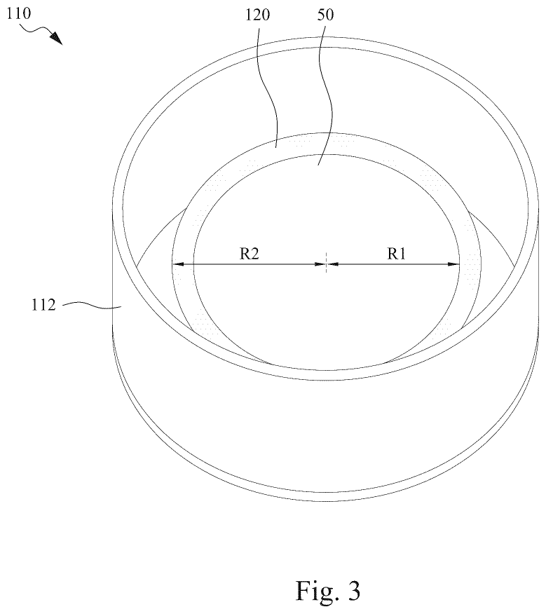

FIG. 1 shows a top view of a microwave annealing (MWA) system 100, in accordance with some embodiments. A process flow in accordance with the embodiments is briefly described below, and some aspects of the process flow and the MWA system 100 are described in greater detail in FIGS. 2 through 4. In some embodiments, the MWA system 100 comprises loading stations 102, a handling chamber 104 comprising a handler 106, a cooling station 108, and an apparatus chamber 110 comprising a process chamber 112. In some embodiments, the MWA system 100 may be used to perform a microwave annealing (MWA) process on a wafer 50, which may be, for example, an annealing process, a heating process, a thermal treatment process, or the like. In some embodiments, MWA system 100 may be configured to perform a MWA process on a wafer 50 that has a radius R1 (see FIGS. 2 and 3) in the range of about 100 mm (e.g. an 8″ wafer) to about 150 mm (e.g., a 12″ wafer), though wafers 50 having other dimensions are possible. In some embodiments, the MWA system 100 may be configured to heat a wafer 50 to a temperature in the range of about 100° C. to about 800° C., though other temperatures are possible. In some embodiments, the MWA system 100 may be configured to heat a wafer 50 for a duration of time between about 10 seconds and about 30 minutes, though other times are possible.

A wafer 50 may be, for example, a semiconductor wafer, such as a silicon wafer, or a semiconductor substrate, such as a bulk semiconductor, substrate a semiconductor-on-insulator (SOI) substrate, or the like, which may be doped (e.g., with a p-type or an n-type dopant) or undoped. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the wafer 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof.

In some embodiments, the wafer 50 is a package component comprising a device wafer, a package substrate, an interposer wafer, or the like. In the embodiments in which the wafer 50 comprises a device wafer, the wafer 50 may include a semiconductor substrate, which may be, for example, a silicon substrate, although other semiconductor substrates are also usable. Active devices may be formed on a surface of the substrate, and may include, for example, transistors. Metal lines and vias may be formed in dielectric layers over the substrate, which may be low-k dielectric layers in some embodiments. The low-k dielectric layers may have dielectric constants (k values) lower than, for example, about 3.5, lower than about 3.0, or lower than about 2.5. The dielectric layers may also comprise non-low-k dielectric materials with dielectric constants (k values) greater than 3.9. The metal lines and vias may comprise copper, aluminum, nickel, tungsten, or alloys thereof. The metal lines and vias interconnect the active devices, and may connect the active devices to overlying metal pads formed on the dielectric layers.

In some embodiments, the wafer 50 may comprise semiconductor dies, such as logic dies including central processing units (CPUs) or graphics processing units (GPUs), memory cells and arrays including e.g. static random access memory (SRAM) arrays, or the like. In other embodiments, the semiconductor dies may include a system-on-a-chip (SoC), an application processor (AP), a microcontroller, a memory die (e.g., dynamic random access memory (DRAM) die, SRAM die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. Any suitable semiconductor devices may be utilized.

In some embodiments, the wafer 50 is an interposer wafer, which is free from active devices therein. The wafer 50 may or may not include passive devices (not shown) such as resistors, capacitors, inductors, transformers, or the like. In some embodiments, the wafer 50 is a package substrate. In some embodiments, the wafer 50 includes laminate package substrates, in which conductive traces are embedded in laminate dielectric layers. In some embodiments, the wafer 50 is a build-up package substrate, which comprises cores and conductive traces built on the opposite sides of the cores.

The loading stations 102 may be used, for example, to load wafers 50 into the handling chamber 104 of the MWA system 100. In some embodiments, the loading stations 102 are front opening unified pods (FOUPs). The handling chamber 104 may include one or more handlers 106 used to transfer wafers 50 between the loading stations 102, the handling chamber 104, the cooling station 108, and the apparatus chamber 110. For example, the handlers 106 may transfer a wafer 50 from a loading station 102 to the process chamber 112 of the apparatus chamber 110. After a MWA process is performed on the wafer 50, the handlers 106 may transfer the wafer 50 from the apparatus chamber 110 to the cooling station 108. In some cases, the handlers 106 may then transfer the wafer 50 from the cooling station 108 to a loading station 102. The handlers 106 may be, for example, transfer robots or robotic arms, which may be located in different areas of the handling chamber 104. The MWA system 100 shown in FIG. 1 is an example, and a MWA system 100 may have a different number or a different configuration of stations, chambers, or components than shown.

FIG. 2 illustrates a cross-sectional view of a process chamber 112 within an apparatus chamber 110, in accordance with some embodiments. FIG. 3 illustrates a three-dimensional view of a process chamber 112, in accordance with some embodiments. Some features shown in FIG. 2 are not shown in FIG. 3 for clarity reasons. The apparatus chamber 110 and the process chamber 112 may be part of a microwave annealing (MWA) system such as the MWA system 100 shown in FIG. 1. Within the process chamber 112 is a susceptor 120 that holds a wafer 50 and that facilitates heating of the wafer 50 during the MWA process. One or more microwave generators 116 are coupled to the process chamber 112 and provide the microwave radiation that causes heating of the wafer 50 within the process chamber 112. A gas inlet 132 may be connected to the process chamber 112 to supply gases to the interior of the process chamber 112, and a gas outlet 134 may be connected to the process chamber 112 to exhaust gases from the interior of the process chamber 112.

In some embodiments, a controller 130 may be connected to the susceptor 120, the microwave generators 116, the gas inlet 132, the gas outlet 134, and/or other components. Operations of the process chamber 112 may be controlled by the controller 130. In some embodiments, the controller 130 comprises a programmable computer. The controller 130 is illustrated as a single element for illustrative purposes. In some embodiments, the controller 130 comprises multiple elements. The controller 130 may be located in the apparatus chamber 110 or in another location in the MWA system 100 or external to the MWA system 100. In some embodiments, the controller 130 may be connected to the handlers 106 and may be configured to control movement of the wafers 50 through a MWA process.

In some embodiments, the process chamber 112 may have an approximately cylindrical shape. See, for example, the process chamber 112 shown in FIG. 3. In some cases, the distribution of the electromagnetic (EM) field within the process chamber 112 is dominated by the superposition of the various EM eigenmodes (e.g., standing waves) within the process chamber 112. In this manner, the EM field distribution of the microwave radiation within the process chamber 112 depends at least partially on the interior shape of the process chamber 112, as the interior shape of the process chamber 112 defines the boundary conditions for the EM eigenmodes. In some cases, a process chamber 112 having a cylindrical shape can provide a more uniform heating of the wafer 50 during a MWA process. In some embodiments, one or more dimensions of the process chamber 112 may correspond to integer multiples of one or more wavelengths of microwave radiation used during the MWA process. For example, the interior of the process chamber 112 may have an interior radius that is in the range of about 120 mm to about 800 mm or an interior height that is in the range of about 50 mm to about 1000 mm, though other dimensions are possible. In some embodiments, the walls of the process chamber 112 may comprise a metal or another material having a high reflectivity for microwave radiation. For example, the walls of the process chamber may be made of one or more materials including steel, stainless steel, nickel, aluminum, other metals, alloys thereof, the like, or combinations thereof. In some embodiments, the walls of the process chamber 112 are configured to withstand the ambient environment (e.g., temperatures and pressures) involved in a MWA process.

The gas inlet 132 may be connected to the process chamber 112 and may supply gases from one or more gas supplies (not shown) to the interior of the process chamber 112. The gas supplies may be located in the apparatus chamber 110, in some embodiments. For example, the gas inlet 132 may supply gases such as nitrogen, oxygen, hydrogen, ammonia, argon, helium, combinations thereof, or the like into the process chamber 112. The gases may be supplied before, during, or after performing a MWA process. The gas outlet 134 may be connected to the process chamber 112 to remove gases, reaction byproducts, or the like from the interior of the process chamber 112. For example, in some embodiments, the gas outlet 134 may be connected to a vacuum pump (not shown). In some embodiments, the gas inlet 132 and/or the gas outlet 134 may be connected to the controller 130. The controller 130 may control the operation of the gas inlet 132, gas outlet 134, gas supplies, vacuum pumps, and/or other components.

In some embodiments, the pressure inside the process chamber 112 may be controlled using the gas inlet 132 and/or the gas outlet 134. For example, the pressure may be controlled by flowing gas into the process chamber 112 using the gas inlet 132 and removing gas from the process chamber 112 using the gas outlet 134. In this manner, the pressure within the process chamber 112 may be controlled before, during, or after performing a MWA process. In some embodiments, the pressure within the process chamber 112 during a MWA process is controlled to be in the range of about 100 mTorr to about 760 Torr, though other pressures are possible.

One or more microwave generators 116 are coupled to the process chamber 112 to supply microwave radiation to the interior of the process chamber 112. In some embodiments, each microwave generator 116 is coupled to the process chamber 112 by a respective microwave inlet (not separately illustrated), which may be, for example, a waveguide, an antenna, or the like. In some embodiments, the microwave generators 116 are located outside of the process chamber 112, such as in the apparatus chamber 110. FIG. 2 shows three microwave generators 116 coupled to the process chamber 112, but any suitable number of microwave generators 116 may be utilized. For example, one, two, three, or more than three microwave generators 116 may be coupled to the process chamber 112. FIG. 2 also shows the microwave generators 116 being coupled to the process chamber 112 at the top of the process chamber 112 and at the sidewalls of the process chamber 112, but the microwave generators 116 may be coupled to the process chamber 112 at different locations or in a different arrangement than shown. For example, in other embodiments, the microwave generators 116 may be coupled to the process chamber 112 only at the top of the process chamber 112, only at the sidewalls of the process chamber 112, at other locations such as the bottom of the process chamber 112, or at a combination of locations. In some embodiments, the microwave generators 116 may be coupled to the process chamber 112 in a symmetrical (e.g., radially symmetrical) arrangement to facilitate more uniform heating of the wafer 50 during a MWA process. In some embodiments, the microwave generators 116 are connected to the controller 130 and may be controlled by the controller 130.

The microwave generators 116 may generate microwave radiation using any suitable technique, such as using a magnetron, using a solid-state power amplifier (SSPA), or using another technique. In some embodiments, the total microwave power generated during a MWA process is in the range of about 50 W to about 5000 W, though other amounts of power are possible. In some embodiments, the frequency of the microwaves generated during a MWA process is in the range of about 300 MHz to about 100 GHz, through other frequencies are possible. The electric field or the magnetic field of the microwave radiation generated during a MWA process may be vertical or may be transverse at the incidence plane.

In some embodiments, the process chamber 112 includes a susceptor 120 configured to hold a wafer 50 during the MWA process. In some embodiments, during the MWA process, the susceptor 120 absorbs microwave energy and dissipates the absorbed energy as heat. In this manner, the susceptor 120 can facilitate heating the wafer 50.

In some embodiments, the dissipation factor (D_{F}) of the susceptor 120 is greater than air (D_{F}≈0.01%). For example, the susceptor 120 may be formed of one or more materials having a dissipation factor greater than about 0.01%, in some embodiments. In some cases, a larger dissipation factor can enhance the absorption of microwave radiation and raise the susceptor 120 to a higher temperature during a MWA process. In some embodiments, the material(s) of the susceptor 120 may be chosen to have a particular dissipation factor in order to have the susceptor 120 heat the wafer 50 to a particular temperature during a MWA process. In this manner, the material(s) of the susceptor 120 may be chosen to optimize a MWA process for a particular application. In some embodiments, the parameters of a MWA process may be adjusted to optimize the MWA process for the materials of the susceptor 120 and/or the wafer 50. In some embodiments, the material of the susceptor 120 may have a dissipation factor or permittivity that is approximately the same as that of the wafer 50. For example, in some embodiments, the susceptor 120 may have a dissipation factor in the range of about 0.05% to about 2% and the wafer 50 may have a dissipation factor in the range of about 0.1% to about 1%. The susceptor 120 and/or the wafer 50 may have other dissipation factors than these examples. In some cases, having a susceptor 120 and a wafer 50 with similar dissipation factors can allow for a more uniform EM field distribution during a MWA process. In some embodiments, the susceptor 120 includes a high-k material. For example, the material of the susceptor 120 may include aluminum oxide (AlO), aluminum nitride (AlN), silicon carbide (SiC), the like, or a combination thereof. Other materials or combinations of materials are possible.

In some embodiments, the susceptor 120 may include support pins 122 and/or lift pins 124. In some embodiments, the support pins 122 are features protruding from the top of the susceptor 120 that support the wafer 50 during a MWA process. The support pins 122 may protrude a height H1 from an upper surface of the susceptor 120 such that a gap (having approximately the height H1) extends between the wafer 50 and the upper surface of the susceptor 120. The height H1 may be in the range of about 1 mm to about 5 mm in some embodiments, though other heights are possible. In some cases, the presence of a gap between the wafer 50 and the susceptor 120 may improve heating uniformity of the wafer 50 during a MWA process. The support pins 122 may be formed of the same material as the susceptor 120 or may be formed of a material different than the material of the susceptor. In some embodiments, the support pins 122 are formed of a material that has a relatively low dissipation factor, a material that is relatively transparent to microwave radiation, and/or a material with a low thermal conductivity. For example, in some embodiments, the support pins 122 may be a material such as quartz (D_{F}≈0.006%) or sapphire (D_{F}≈0.002%), the like, or combinations thereof. Other materials are possible.

In some embodiments, the lift pins 124 may be connected to actuators that raise or lower the lift pins 124 to facilitate loading or unloading of the wafer 50. For example, in some embodiments, a wafer 50 may be placed on the susceptor 120 by extending the lift pins 124 above the support pins 122, placing the wafer 50 on the lift pins 124 (e.g., using a handler 106), and then retracting the lift pins 124 so that the wafer 50 rests on the support pins 122. In some embodiments, a wafer 50 may be removed from the susceptor 120 by extending the lift pins 124 to raise the wafer 50 above the support pins 122 for retrieval (e.g., by a handler 106). The lift pins 124 may be fully or partially recessed within the susceptor 120, in some embodiments. The lift pins 124 may be the same material as the support pins 122 or may be a different material. In some embodiments, the actuators of the lift pins 124 are connected to and controlled by the controller 130. In some embodiments, the susceptor 120 is coupled to an actuator or motor (not shown) that rotates the susceptor 120 during a MWA process.

In some embodiments, the susceptor 120 includes a temperature sensor 126 that is configured to measure a temperature of the wafer 50 during a MWA process. The temperature sensor 126 may be, for example, an infrared (IR) sensor, a pyrometer, or the like. In other embodiments, one or more temperature sensors are mounted elsewhere in the process chamber 112 in addition to or instead of the temperature sensor 126 mounted in the susceptor 120. For example, a temperature sensor may be mounted above the wafer 50. In some embodiments, the susceptor 120 may include more than one temperature sensor 126. In some embodiments, the IR sensor 126 may be connected to and controlled by the controller 130.

In some embodiments, the susceptor 120 may be approximately cylindrical in shape, through other shapes may be possible. For example, the top surface of the susceptor 120 may be approximately circular. The use of an approximately cylindrical susceptor 120 that holds an approximately circular wafer 50 can improve heating uniformity, in some cases. The susceptor 120 may have sidewalls with a substantially vertical profile, a tapered profile, an angled profile, another type of profile, or a combination thereof. In some embodiments, the upper surface of the susceptor 120 has a radius R2 that is about the same as the radius R1 of the wafer 50 or that is greater than the radius R1 of the wafer 50. For example, in some embodiments, the upper surface of the susceptor 120 may have a radius R2 that is in the range of about 100% of R1 to about 200% of R1. In some embodiments, the radius R2 may be in the range of about 100 mm to about 300 mm. In some embodiments, the radius R2 of the susceptor is between about 0 mm and about 150 mm larger than the radius R1 of the wafer 50. In some embodiments, a difference between the radius R2 and the radius R1 less than about one-fourth of a wavelength of microwave radiation used during a MWA process. In other embodiments, a difference between the radius R2 and the radius R1 is about the same as or greater than about one-fourth of a wavelength of microwave radiation used during a MWA process. Other sizes of the radius R2 are possible.

The use of a susceptor 120 having a radius R2 that is about the same as or greater than the radius R1 of the wafer 50 may improve heating uniformity of the wafer 50 during a MWA process. In some cases, a difference between the dissipation factor of the wafer 50 and the dissipation factor of the ambient environment (e.g., air) can result in large changes of the spatial distribution of the EM field near the edges of the wafer 50 during a MWA process. For example, regions of relatively strong EM fields may be formed at or near the edges of the wafer 50, and excessive heating of the wafer 50 may occur near these regions. Large localized changes in the EM field distribution can worsen heating uniformity of the wafer 50, increase the risk of thermal shock to the wafer 50, cause damage or breakage of the wafer 50, and/or degrade performance of devices formed on the wafer 50. In some cases, having the susceptor 120 extend past the edges of the wafer 50 as described herein can cause these regions of relatively strong EM fields to form farther away from the wafer 50 and thus have less impact on the heating of the wafer 50. In some cases, having a radius R2 greater than a radius R1 can cause a smoother change of EM field intensity near the edges of the wafer 50. In this manner, the heating uniformity of the wafer 50 may be improved, and the risk of thermal damage to the wafer 50 may be reduced.

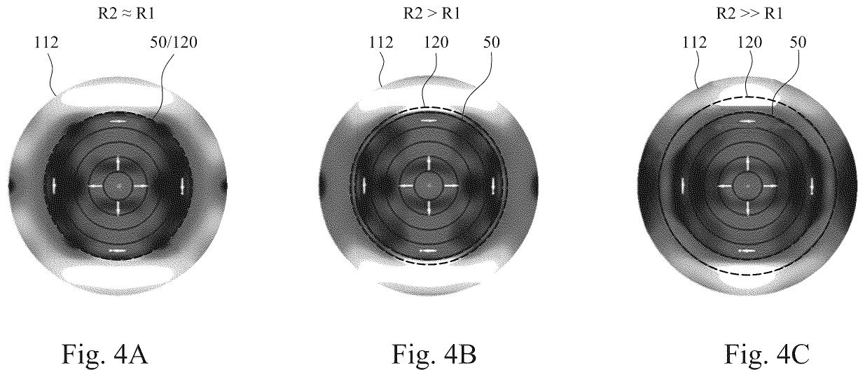

FIGS. 4A-4C, 5A-5C, and 6A-6C show data of simulations of the intensity of the electric field during a MWA process, in accordance with some embodiments. FIGS. 4A, 5A, and 6A show data for an embodiment in which the radius R2 of the susceptor 120 is about the same as the radius R1 of the wafer 50, labeled as “R2≈R1.” FIGS. 4B, 5B, and 6B show data for an embodiment in which the radius R2 of the susceptor 120 is about 7% larger than the radius R1 of the wafer 50, labeled as “R2>R1.” FIGS. 4C, 5C, and 6C show data for an embodiment in which the radius R2 of the susceptor 120 is about 20% larger than the radius R1 of the wafer 50, labeled as “R2>>R1.” The sizes of the radius R2 in FIGS. 4A-6C are for illustrative purposes, and other sizes of the radius R2 are possible.

FIGS. 4A-4C each show the distribution of electric field intensity during a MWA process, in accordance with some embodiments. Specifically, FIGS. 4A-4C are plan views of a process chamber 112 that show the electric field intensity at the plane defined by the top surface of the wafer 50. In FIGS. 4A-4C, brighter regions correspond to stronger electric field intensity and darker regions correspond to weaker electric field intensity. The edges of the wafer 50 and the edges of the susceptor 120 are indicated, showing that the radius R2 of the susceptor 120 of FIG. 4B is larger than the radius R2 of the susceptor 120 of FIG. 4A and that the radius R2 of the susceptor 120 of FIG. 4C is larger than the radius R2 of the susceptor 120 of FIG. 4B. The radius R1 of the wafer 50 is the same for each of FIGS. 4A-4C. FIGS. 4A-4C each show that regions of stronger electric field intensity are formed near opposite edges of the wafer 50. As shown in FIGS. 4A-4C, increasing the radius R2 of the susceptor 120 causes the regions of stronger electric field intensity to form farther away from the edges of the wafer 50. Increasing the radius R2 in this manner can also cause the regions of stronger electric field intensity to have a smaller size (e.g., be more localized). In this manner, FIGS. 4A-4C show that increasing the radius R2 can create a more uniform electric field intensity at the edges of the wafer 50, with less of an increase of electric field intensity near the edges of the wafer 50.

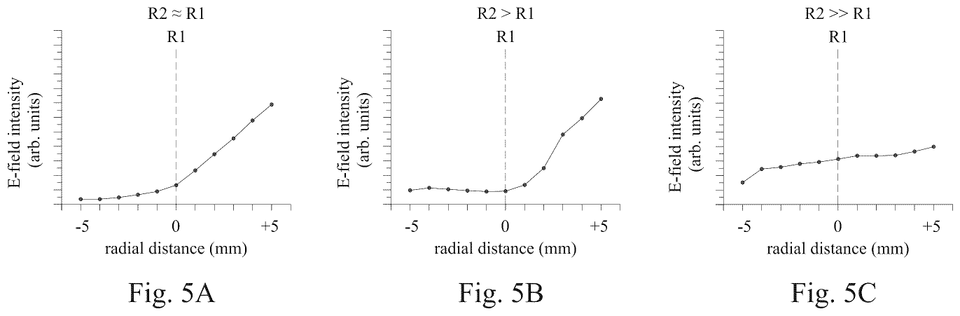

FIGS. 5A-5C each show the average electric field intensity near the edges of the wafer 50 during a MWA process, in accordance with some embodiments. Specifically, FIGS. 5A-5C show, for a range of radial distances from the center of the wafer 50, the average electric field intensity at the plane defined by the top surface of the wafer 50. The range of radial distances includes radial distances within 5 mm of the edge of the wafer 50. The edge of the wafer 50 is indicated by “R1” in FIGS. 5A-5C. The data shown in FIGS. 5A-5C corresponds to the data shown in FIGS. 4A-4C. As shown in FIGS. 5A-5C, increasing the radius R2 of the susceptor 120 reduces the increase of the electric field intensity at the edges of the wafer 50. For example, FIG. 5A shows an increase of electric field intensity at the edge of the wafer 50. In FIG. 5B the increase of the electric field intensity is shifted radially outward beyond the radius R1 of the wafer 50. In FIG. 5C, the increase of electric field intensity is shifted even further, to a radial distance greater than 5 mm beyond the radius R1 of the wafer 50. FIGS. 5A-5C also shows that increasing the radius R2 of the susceptor 120 reduces the variation of the electric field intensity near the edges of the wafer 50. For example, the coefficient of variation (e.g., the standard deviation divided by the average) of the data of FIG. 5A is about 56%, the coefficient of variation of the data of FIG. 5B is about 55%, and the coefficient of variation of the data of FIG. 5C is about 14%. The relatively smaller coefficient of variation of the data of FIG. 5C indicates that the electric field intensity is relatively more uniform.

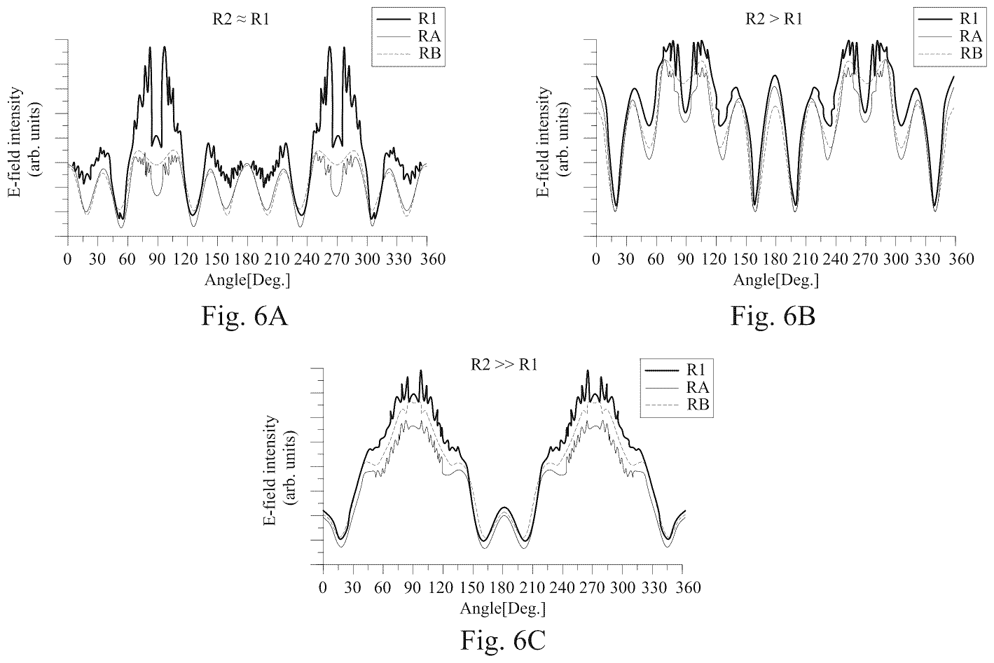

FIGS. 6A-6C each show the electric field intensity near the edges of the wafer 50 during a MWA process, in accordance with some embodiments. Specifically, FIGS. 6A-6C each show the electric field intensity at the surface of the wafer 50 at various angles around the wafer 50. For example, each of FIGS. 6A-6C show the electric field intensity for various angles at a fixed radius R1 (e.g., at the edges of the wafer 50), at a fixed radius RA that is 3 mm smaller than R1, and at a fixed radius RB that is 5 mm smaller than R1. The angle is measured from 0° to 360°, with 0° being at the right edge of the wafers 50 as shown in FIGS. 4A-4C. The data shown in FIGS. 6A-6C corresponds to the data shown in FIGS. 4A-4C. As shown in FIGS. 6A-6C, increasing the radius R2 of the susceptor 120 reduces the differences between the electric field intensities at radius R1, radius RA, and radius RB. For example, FIG. 6A shows a sharp increase in electric field intensity from radius RA to radius R1 near 90° and 270°, and FIGS. 6B and 6C show a much smaller increase. The electric field intensities shown in FIG. 6C also have less strong oscillations than those shown in FIGS. 6A and 6B. In this manner, FIGS. 6A-6C show that increasing the radius R2 can result in smoother and more uniform electric field intensities near the edges of the wafer 50, which can provide improved heating during a MWA process.

In some cases, having a difference between the radius R2 and the radius R1 that is greater than about one-fourth of a wavelength may cause more significant changes to the EM field distribution than having a difference that is smaller than about one-fourth of a wavelength. In this manner, the size of the radius R2 may be controlled to control the EM field distribution, and in some embodiments the radius R2 may be chosen to provide a particular EM field distribution during a MWA process. In some cases, the use of a susceptor 120 as described herein can reduce the non-uniformity of electric field intensity distribution near the edges of a wafer by between about 0% and about 75%, though other percentages are possible.

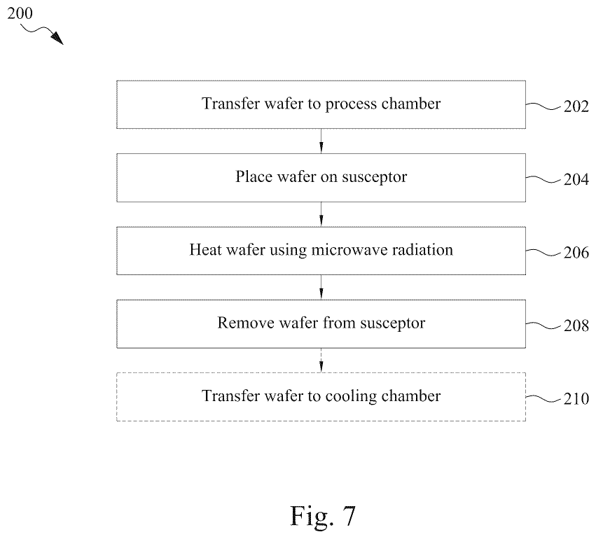

FIG. 7 illustrates a flow chart 200 for performing a microwave annealing (MWA) process using a MWA system, in accordance with some embodiments. The flow chart 200 describes an example MWA process, and more, fewer, or different steps may be used in other embodiments. The MWA system may be similar to the MWA system 100 described previously for FIGS. 1-2, in some embodiments. Some steps or portions of steps may be controlled using a controller 130, in some embodiments. At step 202, a wafer 50 is transferred to the process chamber 112 of the MWA system 100. The wafer 50 may be transferred from a loading station 102 using one or more handlers 106. At step 204, the wafer 50 is placed on a susceptor 120 in the process chamber 112. The susceptor 120 may be similar to the susceptor 120 described previously for FIGS. 2-3. For example, the susceptor 120 may be wider than the wafer 50. In some embodiments, the wafer 50 may be placed on the lift pins 124 and then the lift pins 124 may be lowered to place the wafer 50 on the support pins 122.

At step 206, the wafer 50 is heated using microwave radiation. Heating the wafer 50 using microwave radiation may comprise turning on one or more microwave generators 116, and may including ramping the power of the microwave generators 116 to a target value. In some embodiments, gases are pumped from the process chamber 112 through the gas outlet 134 before the wafer is heated, while the wafer 50 is heated, or after the wafer 50 is heated. In some embodiments, a gas is flowed into the process chamber 112 though the gas inlet 132 before the wafer is heated, while the wafer 50 is heated, or after the wafer 50 is heated. One or more temperature sensors 126 may monitor a temperature of the wafer 50 as the wafer 50 is heated. In some embodiments, the controller 130 may control the operation of the microwave generators 116 based on a temperature of the wafer 50 measured by the one or more temperature sensors 126. After the wafer 50 has been heated as desired, the microwave generators 116 may be turned off. In some embodiments, the power of the microwave generators 116 may be ramped down before the microwave generators 116 are turned off. In some embodiments, step 206 or portions thereof may be performed more than once during a MWA process.

At step 208, the wafer 50 is removed from the susceptor 120. The wafer 50 may be removed, for example, by raising the lift pins 124 to lift the wafer 50 off of the support pins 122. A handler 106 may then secure the wafer 50 and remove it from the process chamber 112. At step 210, the wafer 50 may optionally be transferred to a cooling station 108 by the handler 106. In some embodiments, the wafer 50 is cooled or is allowed to cool in the cooling station 108 until the wafer 50 reaches a target temperature (e.g., 100° C. or another temperature). The wafer 50 may then be transferred to a loading station 102. In some embodiments, the heating uniformity of the MWA process on the wafer 50 may optionally be checked. For example, a sheet resistance map of the wafer 50 may be measured, though other techniques are possible.

Embodiments of the microwave anneal (MWA) system as described herein may achieve advantages. The MWA system described herein may be used for any suitable annealing process, heat treatment, thermal process, or the like. The use of a MWA system with a susceptor having a radius that is about the same as or larger than the radius of a wafer being annealed can improve heating uniformity and reduce the chance of wafer damage. In some cases, the interface between the edges of the wafer and the ambient environment can cause regions near the edges that have large changes in electromagnetic (EM) field. By increasing the size of the susceptor, the abruptness of these large changes in the EM field near the edges of the wafer can be reduced. This can reduce the chance of thermal shock and reduce the chance of thermal damage or breakage. Additionally, the larger radius of the susceptor can cause the regions of large changes in the EM field to form farther from the edges of the wafer. In this manner, the heating uniformity of the wafer for the MWA process may be improved. This can allow the ramp-up rate of microwave power to be increased without increasing the risk of thermal damage, and thus reduce the time needed to perform a MWA process on a wafer. In this manner, yield, uniformity, and reliability can be improved.

In accordance with an embodiment, a method includes placing a wafer on a susceptor, wherein the wafer has a first radius, wherein a top surface of the susceptor has a second radius that is greater than the first radius; using microwave radiation to heat the wafer and the susceptor; and removing the wafer from the susceptor. In an embodiment, the second radius is larger than the first radius by a distance in the range of 0 mm to 150 mm. In an embodiment, the susceptor includes a high-k material. In an embodiment, the method includes rotating the susceptor while using microwave radiation to heat the wafer and the susceptor. In an embodiment, placing the wafer on the susceptor includes extending pins from the top surface of the susceptor; placing the wafer on the pins; and retracting the pins toward the top surface of the susceptor. In an embodiment, while using microwave radiation to heat the wafer and the susceptor, the wafer is held above the top surface of the wafer a distance in the range of 1 mm to 5 mm.

In accordance with an embodiment, a method includes forming devices on a semiconductor wafer; and performing a microwave anneal (MWA) process on the semiconductor wafer, including transferring the semiconductor wafer into a process chamber; placing the semiconductor wafer on a susceptor within the process chamber, wherein after placing the semiconductor wafer, the sidewalls of the susceptor protrude beyond the edges of the semiconductor wafer; generating microwave radiation within the process chamber; removing the semiconductor wafer from the susceptor; and transferring the semiconductor wafer out of the process chamber. In an embodiment, the method includes transferring the semiconductor wafer to a cooling chamber. In an embodiment, generating microwave radiation within the process chamber includes generating microwave radiation using multiple microwave sources; and coupling the microwave radiation into the process chamber using multiple waveguides. In an embodiment, the multiple microwave sources are arranged in a radially symmetrical configuration around the process chamber. In an embodiment, the process chamber and the susceptor are cylindrical.

In accordance with an embodiment, a system includes a microwave source coupled to a chamber, wherein the chamber has a cylindrical shape; and a susceptor within the chamber, wherein the susceptor has a cylindrical shape, wherein a top surface of the susceptor has a circular shape with a first radius, wherein the susceptor is configured to hold a wafer having a second radius that is less than the first radius. In an embodiment, the first radius is between 100% and 200% of the second radius. In an embodiment, the first radius is in the range of 100 mm to 300 mm. In an embodiment, the second radius is in the range of 100 mm to 150 mm. In an embodiment, the system includes a motor configured to rotate the susceptor. In an embodiment, the susceptor includes aluminum oxide. In an embodiment, the susceptor includes an infrared sensor. In an embodiment, the susceptor includes pins protruding from the top surface of the susceptor, wherein the pins hold the wafer. In an embodiment, the pins protrude from the top surface of the susceptor a distance that is in the range of 1 mm to 5 mm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system comprising:
a microwave source coupled to a chamber, wherein the chamber has a cylindrical shape; and
a susceptor within the chamber, wherein the susceptor has a cylindrical shape, wherein a top surface of the susceptor has a circular shape with a first radius, wherein the susceptor is configured to hold a wafer having a second radius that is less than the first radius.

2. The system of claim 1, wherein the first radius is between 100% and 200% of the second radius.

3. The system of claim 1, wherein the first radius is in the range of 100 mm to 300 mm.

4. The system of claim 1, wherein the second radius is in the range of 100 mm to 150 mm.

5. The system of claim 1 further comprising a motor configured to rotate the susceptor.

6. The system of claim 1, wherein the susceptor comprises aluminum oxide.

7. The system of claim 1, wherein the susceptor comprises an infrared sensor.

8. The system of claim 1, wherein the susceptor comprises pins protruding from the top surface of the susceptor, wherein the pins hold the wafer.

9. The system of claim 8, wherein the pins protrude from the top surface of the susceptor a distance that is in the range of 1 mm to 5 mm.

10. An apparatus comprising:
a process chamber;
a microwave generator coupled to the process chamber; and
a susceptor within the process chamber, wherein the susceptor comprises a material having a dissipation factor in the range of 0.05% to 2%, wherein the susceptor is configured to hold a wafer such that the susceptor encircles the wafer in a plan view.

11. The apparatus of claim 10, wherein the process chamber and the susceptor have cylindrical shapes.

12. The apparatus of claim 10, wherein the susceptor is configured to hold the wafer above a top surface of the susceptor a distance in the range of 1 mm to 5 mm.

13. The apparatus of claim 10, wherein the susceptor comprises aluminum nitride.

14. The apparatus of claim 10, wherein the microwave generator is coupled to the process chamber by a waveguide.

15. The apparatus of claim 10, wherein the susceptor comprises a temperature sensor.

16. A system comprising:
a process chamber;
a plurality of microwave sources coupled to the process chamber, wherein the plurality of microwave sources are configured to generate a first wavelength of microwave radiation within the process chamber; and
a susceptor within the process chamber, wherein the susceptor is configured to hold a wafer above a top surface of the susceptor, wherein a first width of the susceptor is greater than a second width of the wafer, wherein the first width is greater than the second width by a distance that is less than one half of the first wavelength of microwave radiation.

17. The system of claim 16, wherein the susceptor has a circular shape.

18. The system of claim 16, wherein the microwave sources are radially arranged around the process chamber.

19. The system of claim 16, wherein the susceptor comprises silicon carbide.

20. The system of claim 16, wherein the susceptor comprises pins protruding from a top surface of the susceptor, wherein the pins comprise a material having a dissipation factor smaller than a dissipation factor of the susceptor.
